(19) United States
(12) Patent Application Publication
(10) Pub. No.: US 2006/0125057 A1
(43) Pub. Date: Jun. 15, 2006

(54) Method for the production of a composite sicoi-type substrate comprising an epitaxy stage

(76) Inventors: Lea Di Cioccio, Saint Ismier (FR); Francois Templier, Voiron (FR); Thierry Billon, Coublevie (FR); Fabrice Letertre, Grenoble (FR)

Correspondence Address: Thelen Reid & Priest, P O Box 640640, San Jose, CA, 95164-0640, US

(21) Appl. No.: 10/526,657

(22) PCT Filed: Sep. 1, 2003
(86) PCT No.: PCT/FR03/50044

§ 371 Date: Mar. 2, 2005

(30) Foreign Application Priority Data
Sep. 3, 2002 (FR) 02/10884

(51) Int. Cl. H01L 31/0312; H01L 29/06

(52) U.S. Cl. 257/619; 257/618; 257/77

(57) ABSTRACT

The invention relates to an SiCOI type composite substrate manufacturing method comprising the following steps:
supply of an initial substrate comprising an Si or SiC support (1) bearing a layer (2) of SiO2 whereon a thin layer (3) of SiC is transferred,
epitaxy of SiC (4) on the thin layer (3) of SiC. The epitaxy is conducted at the following temperatures
from 1450° C. to obtain 6H or 4H polytype epitaxy (4) on a transferred thin 6H or 4H polytype layer (3) respectively, if the support (1) consists of SiC,
from 1350° C. to obtain 3C polytype epitaxy (4) on a transferred thin 3C polytype layer (3), if the support (1) consists of Si or SiC,
from 1350° C. to obtain 6H or 4H polytype epitaxy (4) on a transferred thin 6H or 4H polytype layer (3) respectively, if the support (1) consists of Si.

### FIELD OF THE INVENTION

The invention relates to an SiCOI type composite substrate manufacturing method comprising an epitaxy step conducted on the SiC layer of the composite substrate.

### STATE OF THE RELATED ART

Silicon carbide or SiC is a material with physicochemical and electronic properties well suited to power electronics. These power devices operate in vertical mode, the active layer being an epitaxially grown layer on a monocrystalline SiC substrate. Unfortunately, the solid substrate crystalline growth is carried out by means of a sublimation type technique at over 2000° C. and does not make it possible to obtain substrates with qualities, diameters and costs that are comparable with silicon substrates, for example.

Therefore, the manufacture of composite substrates comprising a thin monocrystalline SiC layer fixed firmly with a low-cost base substrate (polycrystalline SiC or monocrystalline SiC degraded in terms of crystalline quality or silicon) for example represents significant interest.

To produce a power device such as a Schottky diode, PIN diode or power switch on SiC, the properties required for the SiC solid substrate are a low electrical resistivity, excellent thermal conductivity and good epitaxial quality of the epitaxially grown active layer on said substrate. However, these substrates are not available in four inch sizes and are also very expensive.

At the present time, power devices are produced using substrates and 4H or 6H polytype epitaxy. However, the silicon carbide cubic polytype which has suitable properties for the production of such devices is not available as a solid substrate.

The manufacture of said composite substrates, generally obtained by means of the technique known as Smart-Cut®, allows complete freedom in the choice of the bonding barrier between the transferred thin monocrystalline layer and the support and also in the choice of the electrical resistivity of said support. The document FR A 2 774 214, corresponding to the U.S. Pat. No. 6,391,799, discloses an SOI structure production method. However, in the case of SiC, these transferred layers have a thickness of the order of 1 μm and typically 0.5 μm to obtain an electric activity in said layer.

The production of devices, on this type of composite substrate, would require further epitaxy to obtain an active layer with no limitation in thickness, necessary for the voltage strength of the power components.

It is possible to product SiCOI arrangements (SiC/oxide/base) by means of various techniques.

A first solution consists of starting with an SOI substrate (obtained using the SIMOX or Smart-Cut® methods) and subjecting the cubic SiC to further epitaxial growth after partial conversion of the surface silicon layer. In this case, only the 3C polytype is obtained. In addition, holes are created in the oxide layer as reported in the articles “Selective Deposition of 3C—SiC Epitaxially Grown on SOI Substrates” by M. Eickhoff et al., Materials Science Forum Vols. 353-356 (2001) pages 175 to 178 and “Role of SIMOX defects on the structural properties of β-SiC/SIMOX” by G. Ferro et al., Materials Science and Engineering B61-62 (1999) pages 586 to 592. It has been observed that these defects could be reduced by eliminating the holes in the surface SiC layer. It has also been suggested, but without success, to insert an Si3N4 layer. With this respect, it is possible to refer to the article “Stabilization of the 3C—SiC/SOI system an intermediate silicon nitride layer” by S. Zappe et al., Materials Science and Engineering B61-62 (1999), pages 522 to 525. The cubic polytype is epitaxially grown at a temperature of the order of 1350° C. and the trend is to develop methods at temperatures of approximately 1250° C. to limit oxide degradation.

A second solution consists of producing an SiC material arrangement on an electrically insulating substrate. For example, this may consist of an SiC/oxide/Si arrangement. This arrangement is produced using the Smart-Cut® method. It offers the advantage of making it possible to obtain 6H, 4H and 3C SiC as a transferred thin layer. However, as explained above and in view of the use of equipment used as standard in the microelectronics industry, particularly ionic implantation equipment, the maximum thickness of electrically transferred active SiC films is of the order of 1 μm.

To produce electronic devices, it is frequently necessary to use a thicker SiC thin layer with different and strictly controlled doping levels. Therefore, it appears to be necessary to apply an epitaxial deposition step as is the case for SiC solid substrates. However, further epitaxy on such composite substrates poses problems for two main reasons.

First of all, the presence of the silicon support limits the epitaxy temperature to around 1413° C. maximum if the silicon is not to melt. However, the temperature is barely sufficient to obtain 6H and 4H polytypes (1450° C. would make it possible to obtain better results). Cubic SiC inclusions in the layer are observed with the slightest surface defect. Moreover, unintentional doping of SiC layers is increased at low temperatures.

In addition, the presence of oxide should make it impossible for the pseudo-substrate to withstand the epitaxy temperatures required for silicon carbide. Indeed, at conventional epitaxy temperatures, i.e. 1450° C. and above, the oxide is subject to significant corrosion in a hydrogen environment which is the environment used for epitaxy. This is confirmed by the article “Selective Epitaxial Growth of Silicon Carbide on Patterned Silicon Substrates using Hexachlorodisilane and Propane” by Chacko Jacob et al., Materials Science Forum Vols. 338-342 (2000), pages 249 to 252. However, even without a hydrogen environment, in a vacuum, the oxide vaporises from 1200° C. It would be possible to envisage replacing silicon oxide as the bonding layer by silicon nitride, however, for numerous applications, it is very important from an electrical point of view to have an embedded silicon oxide layer.

A third solution consists of producing an SiC material arrangement on an electrically insulating substrate withstanding high temperatures. It is thus possible to produce an SiCOI substrate on a polycrystalline SiC or monocrystalline SiC support of poor quality or on another support withstanding high temperatures. It consists of the same arrangement as above where the support silicon is, for example, replaced by polycrystalline SiC. This makes it possible to do away with the problem of molten silicon. However, the problem of oxide degradation remains. Such an arrangement is obtained by means of the Smart-Cut® method. The SiC in the thin layer is of the desired polytype.

The corresponding technical literature does not apparently report on research on 6H or 4H polytype SiC epitaxy on SiCOI substrates. This is due to the fact that it is acknowledged that, for temperatures of up to 1350° C., the quality of 6H and 4H polytype epitaxy will be poor (case of epitaxy on SICOI with silicon support plate). In addition, over 1400° C., the oxide will be degraded, i.e. destroyed, or recrystallised.

### DESCRIPTION OF THE INVENTION

However, the inventors of the present invention succeeded in carrying out epitaxy on all these different types of materials and unexpectedly obtained several satisfactory results.

The oxide was not degraded at high temperatures (1410° C.-1600° C.) when the epitaxy was conducted on SiCOI substrates formed from an SiC support successively bearing a silicon oxide layer and a thin SiC layer, making it possible to produce high quality epitaxy, comparable to epitaxy on solid sic.

The inventors also conducted 6H and 4H polytype SiC epitaxy on SiCOI substrates wherein the support is made of silicon. Encouraging results were obtained.

Therefore, the invention relates to an SiCOI type composite substrate manufacturing method comprising the following steps:

supply of an initial substrate comprising an Si or SiC support bearing a layer whereon a thin layer of SiC is transferred,

epitaxy of SiC on the thin layer of SiC,

characterised in that the epitaxy is conducted at the following temperatures:

from 1450° C. to obtain 6H or 4H polytype epitaxy transferred thin 6H or 4H polytype layer respectively, if the support consists of SiC,

from 1350° C. to obtain 3C polytype epitaxy on a transferred thin 3C polytype layer, if the support consists of Si or SiC,

from 1350° C. to obtain 6H or 4H polytype epitaxy on a transferred thin 6H or 4H polytype layer respectively, if the support consists of Si.

Before the epitaxy step, it is possible to provide for an initial substrate preparation step to improve the surface quality of the transferred thin SiC layer. This preparation step may consist of subjecting the surface of the transferred thin SiC layer to an operation selected from polishing, etching and hydrogen etching.

Several SiC layers can be successively grown epitaxially on the thin SiC layer.

The invention also relates to the use of an SiCOI type composite substrate obtained by means of the above manufacturing method to produce semiconductor devices.

The invention also relates to a semiconductor device produced on an SiCOI type composite substrate obtained by means of the above manufacturing method.

### BRIEF DESCRIPTION OF FIGURES

The invention will be understood more clearly and other advantages and characteristics will emerge upon reading the following description, given as a non-restrictive example, accompanied by the appended figures, wherein:

FIG. 1 is a cross-sectional view of an SiCOI substrate wherein the thin SiC layer has received SiC epitaxy, according to the invention,

FIG. 2 is a cross-sectional view of a Schottky diode produced by applying the method according to the invention,

FIG. 3 is a cross-sectional view of a PIN type bipolar diode produced by applying the method according to the invention,

FIG. 4 is a cross-sectional view of a MESFET transistor produced by applying the method according to the invention,

FIG. 5 is a cross-sectional view of a MOSFET transistor produced by applying the method according to the invention.

### DETAILED DESCRIPTION OF EMBODIMENTS OF THE INVENTION

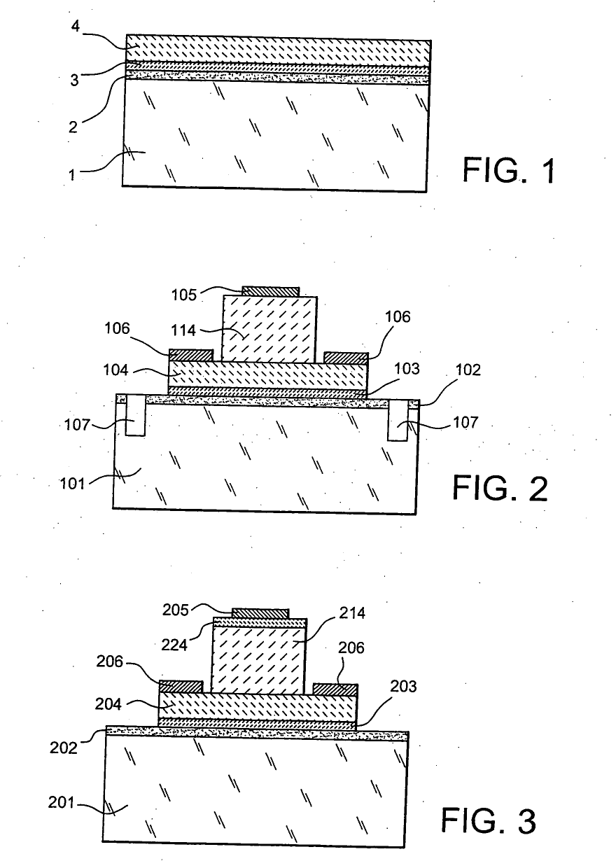

SiC epitaxial growths were produced on SiCOI substrates such as that represented in FIG. 1 and formed from a support 1 successively bearing a silicon oxide layer 2 and a thin SiC layer 3. The thin layer 3 is a transferred layer. The transfer may be obtained by means of the Smart-Cut® technique.

For an SiC support 1 en SiC, 6H and 4H polytype SiC epitaxy was conducted on thin 6H and 4H polytype layers 3 respectively at a temperature of 1450° C. to 1550° C. 3C polytype SiC epitaxy was also conducted on a thin 3C polytype layer 3 from 1350° C. These epitaxially grown layers are referenced 4 in FIG. 1.

During the epitaxy, the pressure was atmospheric pressure or vacuum pressure. The gases used were hydrogen H2 for a flow of 3 to 200 l/min, silane SiH4 at a rate of 4 to 2000 sccm and propane C3H8 at a rate of 4 to 2000 sccm. The doping agent used to deposit doped SiC layers was nitrogen at a rate of 2 to 2000 sccm. The epitaxy was conducted by means of a CVD technique.

Prior to the epitaxy, the thin layer 3 may be prepared by means of polishing or etching in order to improve the surface. It is also possible to perform in situ hydrogen etching of the surface of the thin layer 3.

The epitaxial qualities and the doping levels obtained are equivalent to those obtained using solid substrates.

6H and 4H polytype SiC epitaxy on SiCOI substrates with thin SiC layers of corresponding polytypes and silicon supports was also conducted.

Unexpectedly, good quality epitaxy was obtained at 1400° C. on a transferred thin 4H polytype SiC layer with a surface disorientation of 8° off.

In the case of a thin 6H polytype SiC layer, cubic inclusions were observed. This is probably due to the surface disorientation of the material used for the thin layer. This disorientation was 3.5° off. It has emerged that a disoriented thin 6H SiC layer of 8° off would give the same result as for the above thin 4H SiC layer.

It is also possible to grow 3C SiC epitaxially from 1413° C. using initial composite substrates formed from an SiC support 1, and silicon oxide layer 2 and a thin 3C SiC layer. Using an SiC support rather than a silicon support makes it possible to perform epitaxy at higher temperatures.

With the method according to the invention, the advantages of the epitaxy process on solid substrates are retained:

epitaxial quality of active layer equivalent to the epitaxial quality on this substrate,

low resistance in the conducting state according to the component architecture, the choice of support plate or doping of the base for the ohmic contact,

good thermal conductivity (according to component architecture).

Additional advantages are even obtained

possibility to have a lower electrical resistivity since the n+ conducting support is produced by epitaxy and can achieve higher doping levels that those of substrates,

possibility to use four inch or greater diameter base plates to be compatible with silicon production lines.

The demonstration of the feasibility of these types of epitaxy makes it possible to envisage numerous applications. Indeed, due to the demonstration of these possibilities, the SiC thickness on oxide can be increased in a controlled manner without limitation, which is not the case for arrangements comprising a transferred SiC film wherein the thickness is limited to approximately 1 μm. Re-epitaxy also enables the technological arrangement of different doping layers, which is obviously not the case for SiCOI alone.

Several applications can be mentioned as an example.

The epitaxially grown layer(s) make(s) it possible to produce a pseudo-vertical device on SiC and insulating substrate (SiCOI) irrespective of the transfer support.

FIG. 2 is a cross-sectional view of a Schottky diode produced by applying the method according to the invention. The initial SiCOI substrate comprises an SI or SiC support 101 successively bearing a silicon oxide layer 102 and an added or transferred thin SiC layer 103. Two successive epitaxial SiC growths were carried out to obtain an n+ doped first epitaxially grown layer 104 and an n− doped second epitaxially grown layer 114. Lithographic levels make it possible to obtain the structure represented in FIG. 2 and the Schottky contact 105 on the epitaxially grown layer 114 and the ohmic contacts 106 on the epitaxially grown layer 104. Etching 107 makes it possible to insulate the structure obtained.

The front contact on the buffer layer 104, strongly doped and epitaxially grown under the active layer 114, replaces the rear contact on devices according to the prior art. The epitaxially grown layers have higher doping levels than commercially available substrates, which is another advantage.

FIG. 3 is a cross-sectional view of a PIN type bipolar diode produced by applying the method according to the invention. The initial SiCOI substrate comprises an Si or SiC support 201 successively bearing a silicon oxide layer 202 and an added or transferred thin SiC layer 203. Three successive epitaxial SiC growths were carried out to obtain an n+ doped first epitaxially grown layer 204, an n− doped second epitaxially grown layer 214 and a p doped third epitaxially grown layer 224. Lithographic levels make it possible to obtain the structure represented in FIG. 3 and the ohmic contact 205 on the epitaxially grown layer 224 and the ohmic contacts 206 on the epitaxially grown layer 204.

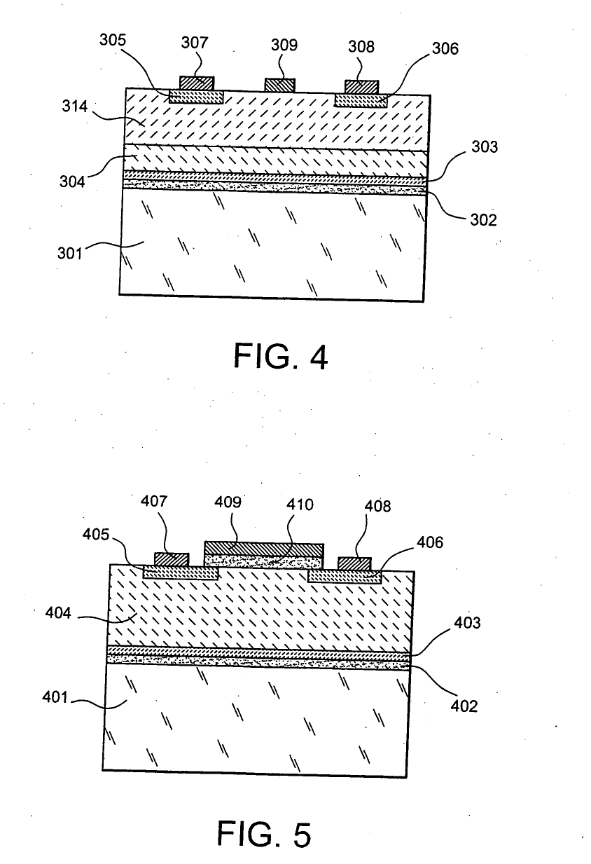

FIG. 4 is a cross-sectional view of a MESFET transistor produced by applying the method according to the invention. The initial SiCOI substrate comprises an Si or SiC support 301 successively bearing a silicon oxide layer 302 and an added or transferred thin SiC layer 303. Two successive epitaxial SiC growths were carried out to obtain a p− doped first epitaxially grown layer 304 or forming a semi-insulating buffer layer and an n− doped second epitaxially grown layer 314. Two surface zones 305 and 306 of the second epitaxially grown layer were n+ doped by implantation. Ohmic contacts 307 and 308 were produced on the surface zones 305 and 306 respectively. A Schottky contact 309 was produced on the second epitaxially grown layer 314, between the surface zones 305 and 306.

FIG. 5 is a cross-sectional view of a MOSFET transistor produced by applying the method according to the invention. The initial SiCOI substrate comprises an Si or SiC support 401 successively bearing a silicon oxide layer 402 and an added or transferred thin SiC layer 403. Epitaxial SiC growth was carried out to obtain a p doped epitaxially grown layer 404. Two surface zones 405 and 406 of the epitaxially grown layer were n+ doped by implantation. Ohmic contacts 407 and 408 were produced on the surface zones 405 and 406 respectively. Between the ohmic contacts 407 and 408, a silicon oxide layer 410 was created to overlap with the surface zones 405 and 406. Finally, a gate 409, made of polysilicon for example, was deposited on the gate oxide layer 10.

More generally, the invention applies to any device for which the active layer obtained by means of Smart-Cut® type transfer on an insulating type substrate on material does not have a satisfactory thickness or electrical qualities.

The demonstration of the epitaxy on this type of support makes it possible to extrapolate the use of transferred SiC arrangements (with support plate that withstands the epitaxy temperature in question) to prepare solid substrates used them as seed growth for any high growth rate epitaxy technique.

The demonstration of monocrystalline 3C SiC epitaxy on a support other than silicon makes it possible to envisage the use of this material for high-power and even hyperfrequency applications for this particular polytype.

1. SiCOI type composite substrate manufacturing method comprising the following steps:
supply of an initial substrate comprising an Si or SiC support bearing a layer of SiO2 whereon a thin layer of SiC is transferred,
epitaxy of SiC on the thin layer of SiC,
wherein the epitaxy is conducted at the following temperatures
from 1450° C. to obtain 6H or 4H polytype epitaxy on a transferred thin 6H or 4H polytype layer respectively, if the support consists of SiC,
from 1350° C. to obtain 3C polytype epitaxy on a transferred thin 3C polytype layer, if the support consists of Si or SiC,
from 1350° C. to obtain 6H or 4H polytype epitaxy on a transferred thin 6H or 4H polytype layer respectively, if the support consists of Si.

2. Method according to claim 1, wherein before the epitaxy step, an initial substrate preparation step is provided for to improve the surface quality of the transferred thin SiC layer.

3. Method according to claim 2, wherein the preparation step consists of subjecting the surface of the transferred thin SiC layer to an operation selected from polishing, etching and hydrogen etching.

4. Method according to claim 1, wherein several SiC layers are successively grown epitaxially on the thin SiC layer.

5. Use of the SiCOI type composite substrate obtained by means of the manufacturing method according to claim 1 of claims 1 to 4 to produce semiconductor devices.

6. Semiconductor device produced on an SiCOI type composite substrate obtained by means of the manufacturing method according to claim 1.
